(19) United States
(12) Patent Application Publication
(10) Pub. No.: US 2013/0286557 A1
(43) Pub. Date: Oct. 31, 2013

(54) Frame for LCD Device and LCD Device

(71) Applicants: Yicheng Kuo, Shenzhen (CN); Shihhsiang Chen, Shenzhen (CN); Gang Yu, Shenzhen (CN); Gege Zhou, Shenzhen (CN); Weifeng Chen, Shenzhen (CN)

(72) Inventors: Yicheng Kuo, Shenzhen (CN); Shihhsiang Chen, Shenzhen (CN); Gang Yu, Shenzhen (CN); Gege Zhou, Shenzhen (CN); Weifeng Chen, Shenzhen (CN)

(21) Appl. No.: 13/515,514

(22) PCT Filed: May 9, 2012
(86) PCT No.: PCT/CN12/75220

§ 371 Date: Jun. 13, 2012

(30) Foreign Application Priority Data
Apr. 28, 2012 (CN) 201210132044.0

(51) Int. Cl. H05K 7/00; H05K 7/18

(52) U.S. Cl. 361/679.01; 312/223.1

(57) ABSTRACT

The invention relates to the field of LCDs, and more particularly to a frame for an LCD device and an LCD device including the frame. The frame includes four edge frames; at least one pair of mutually parallel edge frames of the four edge frames are separately provided with a ripple structure. The ripple structure of the invention is similar to a telescopic ripple part of a drinking straw. The dimensions of one pair of edge frames provided with the ripple structure in the length direction can be adjusted. When the dimensions of two or more kinds of frames are different but similar, a same frame can be shared to achieve the effect of one object with multiple purposes, thereby reducing the number and development cost of special moulds, shortening the development cycle of the product, and avoiding the problem that a great deal of stagnant materials are inconveniently handled when developing single device. Thus, the aim of reducing cost is achieved.

### TECHNICAL FIELD

The invention relates to the field of liquid crystal displays (LCDs), and more particularly to a frame for an LCD device and an LCD device.

### BACKGROUND

As shown in FIG. 1, a conventional LCD device generally includes a front frame 1, an LCD panel 2, a middle frame 3, a backlight module 4, a back cover 5 and the like. The backlight module 4 includes an optical film, a light guide panel (LGP), a lightbar and the like. The front frame 1, the middle frame 3, and the back cover 5 respectively have different functions. The front frame 1 is mainly used for fixing the LCD panel 2 and preventing the LCD panel 2 from escaping. The middle frame 3 is mainly used for bearing the LCD panel 2 and shielding partial backlight module 4 from light leakage, and the back cover 5 is mainly used for bearing the optical film, the LGP, the lightbar and the like and ensuring the planeness of the backlight module 4.

The dimensions of LCD devices are increasingly varied. Different dimensions of LCD devices require different dimensions of front frames, middle frames, and back covers. The front frame and the middle frame of conventional LCD devices are generally made by integrated injection molding, thereby requiring independently designing and manufacturing the front frame or the middle frame and manufacturing corresponding special moulds even if they have similar dimensions. Because the mould cannot be shared and has a long development cycle, the cost of the front frame and the middle frame is restricted from being reduced, and the development cycle of the LCD devices is restricted from being shortened.

### SUMMARY

In view of the above-described problems, the aim of the invention is to provide a frame for an LCD device and an LCD device comprising the frame with adjustable dimension.

A first technical scheme of the invention is that: a frame for an LCD device comprises four edge frames; at least one pair of mutually parallel edge frames of the four edge frames are separately provided with a ripple structure. The frame is formed by joining a plurality of frame edge members, each frame edge member is provided with the ripple structure, and there is a plurality of ripple structures in the edge frame with the ripple structure. The natural lengths of all the frame edge members are the same. The frame is formed by joining a plurality of frame edge members and a plurality of frame corner members.

A second technical scheme of the invention is that: a frame for an LCD device comprises four edge frames; at least one pair of mutually parallel edge frames of the four edge frames are separately provided with one ripple structure.

Preferably, there is a plurality of ripple structures in the edge frame with the ripple structure, thereby increasing the adjusting range of the frame dimension.

Preferably, the frame is formed by joining a plurality of frame edge members. The frame employs a modular design, namely the frame is divided into a plurality of frame edge member units, and the design of the frame edge member unit is standardized. Thus, when the new product of LCD devices is developed, the frame edge members of different number are selected from the standardized modular units for matching and use. The frame edge member has a high generality, thereby reducing the development cost of special moulds, shortening the development cycle of the product, and achieving the aim of reducing cost.

Preferably, there is a plurality of ripple structures in the edge frame with the ripple structure, thereby increasing the adjusting range of the frame dimension.

Preferably, each frame edge member is provided with the ripple structure, and the natural lengths of all the frame edge members are the same. Frames of various dimensions can be formed by joining only one kind of frame edge member. Although the length and width dimensions of the formed frame may not meet requirements, the dimension can be adjusted within a certain range by using the adjustment capacity of the ripple structure in the frame edge member.

Preferably, the frame is formed by joining a plurality of frame edge members and a plurality of frame corner members. The frame employs the modular design, namely the frame is divided into a plurality of frame edge member units and frame corner member units, and the designs of the frame edge member unit and the frame corner member unit are standardized. The frame is formed by joining different number of frame edge members matched with the frame corner members. The corner strength of the frame employing the frame corner member is higher.

Preferably, the ripple structure is arranged in the frame edge member or/and the frame corner member.

Preferably, there is a plurality of ripple structures in the edge frame with the ripple structure, thereby increasing the adjusting range of the frame dimension.

Preferably, all the frame edge members and the frame corner members are separately provided with the ripple structure.

The invention further provides a third technical scheme: an LCD device comprises the frame for an LCD device mentioned above; the frame is a front frame or a middle frame.

Advantages of the invention are summarized below: at least one pair of mutually parallel edge frames of the four edge frames of the frame for an LCD device of the invention are separately provided with one ripple structure; the ripple structure is similar to a ripple part of a drinking straw. The natural length of the ripple structure in the axial direction thereof can be adjusted within a certain range, or the ripple structure can be accordingly stretched or shortened under the condition of being stretched or compressed by applying small outside force; thus, the dimension of one pair of edge frames with ripple structures in the length direction can be adjusted. When the dimensions of two or more kinds of frames are different but similar, the same frame can be shared to achieve the effect of one object with multiple purposes, thereby reducing the number and development cost of special moulds, shortening the development cycle of the product, avoiding the problem that a great deal of stagnant materials are inconveniently handled when developing single device. Thus, the aim of reducing cost is achieved.

### BRIEF DESCRIPTION OF FIGURES

FIG. 1 is a schematic diagram of a conventional LCD device;

FIG. 2 is a schematic diagram of a frame for an LCD device of a first example of the invention;

FIG. 3 is an enlarged view of a ripple structure shown in FIG. 2;

FIG. 4 is a schematic diagram of a frame for an LCD device of a second example of the invention;

FIG. 5 is a schematic diagram of a frame for an LCD device of a third example of the invention;

FIG. 6 is a schematic diagram of a frame for an LCD device of a fourth example of the invention;

FIG. 7 is a schematic diagram of a frame for an LCD device of a fifth example of the invention; and

FIG. 8 is a three-dimensional diagram of a frame for an LCD device of a fifth example of the invention.

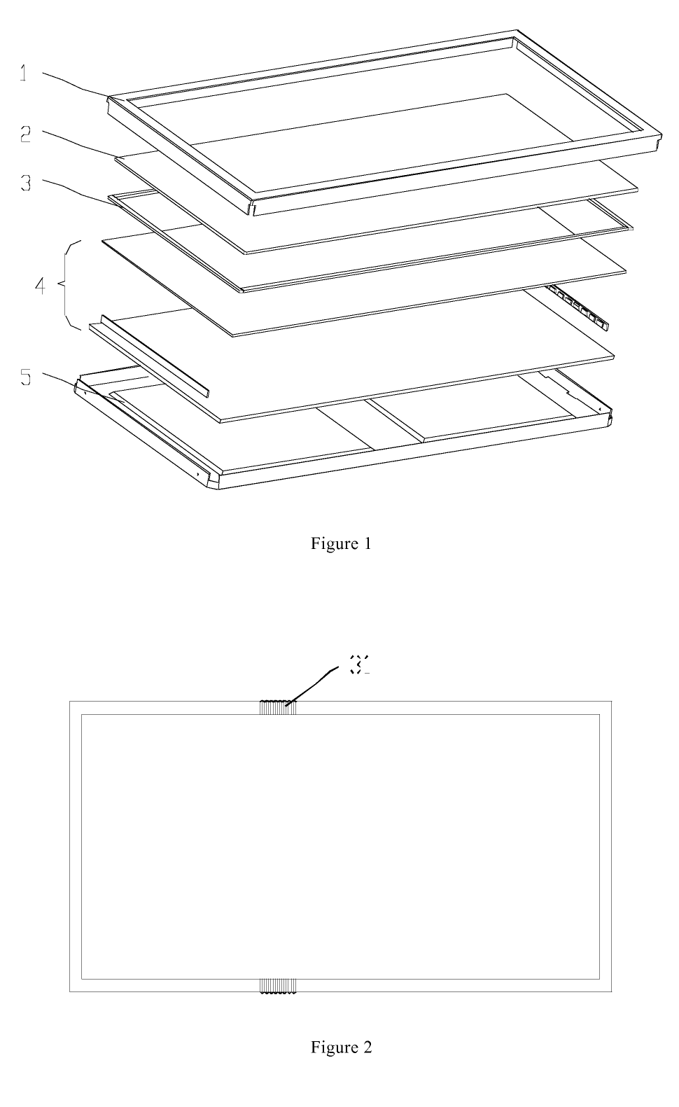

Legends: 1. front frame; 2. LCD panel; 3. middle frame; 31. ripple structure; 32. frame edge member; 33. frame corner member; 4. backlight module; 5. back cover.

### DETAILED DESCRIPTION

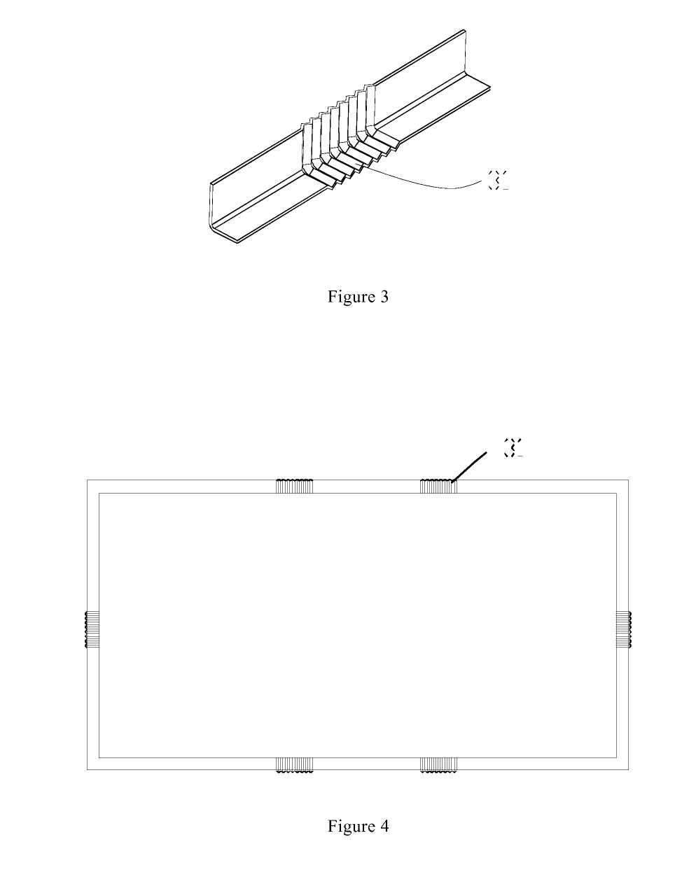

The invention provides an LCD device, which comprises a frame. The frame can be a front frame or a middle frame. FIG. 2 and FIG. 3 show a first example of the frame for an LCD device of the invention. The frame comprises four edge frames; at least one pair of mutually parallel edge frames of the four edge frames are separately provided with a ripple structure 31. In the example, only one pair of edge frames of the frame in the length direction are separately provided with one ripple structure 31, and the cross section of the frame is in an L shape.

One pair of mutually parallel edge frames of the four edge frames of the frame for an LCD device of the invention are separately provided with one ripple structure 31, and the ripple structure 31 is similar to a ripple part of a drinking straw. The natural length of the ripple structure in the axial direction thereof can be adjusted within a certain range, or the ripple structure can be accordingly stretched or shortened under the condition of being stretched or compressed by applying small outside force. The length and pitch of the ripple structure 31 are crucial factors which affect the dimension adjusting range of the ripple structure 31, and the length and pitch of the ripple structure 31 can be purposefully designed according to the practical situation. The dimension of one pair of edge frames provided with ripple structures 31 in the length direction can be adjusted. When the dimensions of two or more kinds of frames are different but similar, such as the difference of several centimeters in the length, the same frame can be shared to achieve the effect of one object with multiple purposes, thereby reducing the number and development cost of special moulds, shortening the development cycle of the product, avoiding the problem that a great deal of stagnant materials are inconveniently handled when developing single device. Thus, the aim of reducing cost is achieved.

Because the frame of the example is integratedly formed, a method for adjusting the dimension of the frame can comprise: enlarging the dimension of the frame by a large-size component in the frame, for example, an LCD panel is forcibly pressed in the middle frame to enlarge the dimension of the middle frame by the LCD panel, or enlarging the dimension of the front frame by a back frame; alternatively, clamping the frame of the invention in other frames with fixed dimension, and narrowing the frame of the invention by the clamping force of the frame with fixed dimension, etc.

FIG. 4 shows a second example of the frame for an LCD device of the invention, and the second example is different from the first example in that: there is a plurality of ripple structures 31 in the edge frame with the ripple structure 31. Specifically, in the example, one pair of edge frames of the frame in the length direction are separately provided with two ripple structures 31, and the other pair of edge frames in the width direction are separately provided with one ripple structure 31. Both the dimensions of the frame in the length and width directions can be adjusted, and the dimension in the length direction can be adjusted to a greater extent. When the difference between the two frame dimensions is slightly large, such as more than ten centimeters, the scheme of the example can be employed.

FIG. 5 shows a third example of the frame for an LCD device of the invention, and the third example is different from the second example in that: the frame is formed by joining a plurality of edge frame members 32. Specifically, in the example, the edge frame in the length direction comprises four frame edge members 32, and the edge frame in the width direction comprises two frame edge members 32; the four edge frames of the frame are separately provided with one ripple structure 31, and the ripple structure 31 is arranged in one of the frame edge members 32. In the example, the dimensions of the frame in both length direction and width direction can be adjusted.

The frame of the example employs a modular design, namely the frame is divided into a plurality of frame edge member units, and the design of frame edge member unit is standardized. Thus, when the new product of LCD devices are developed, the frame edge members of different number are selected from the standardized modular units for matching and use. When a conventional frame edge member unit is not satisfied to form a frame with a certain dimension, one or more frame edge members with the ripple structure can be added. Thus, the frame edge member has a high generality, thereby reducing the development cost of special moulds, shortening the development cycle of the product, and achieving the aim of reducing cost.

When the frame is segmentally designed and the frame edge members are separately fixed on a back cover, a gap is easily generated between two adjacent frame edge members, resulting in light leakage. Because the dimension of the frame of the invention can adjusted, the gap between two adjacent frame edge members is narrowed as far as possible, thereby preventing light leakage.

Optionally, in the example, a plurality of ripple structure can be arranged in the same frame edge member, to achieve the aim of adjusting the frame in a certain length direction.

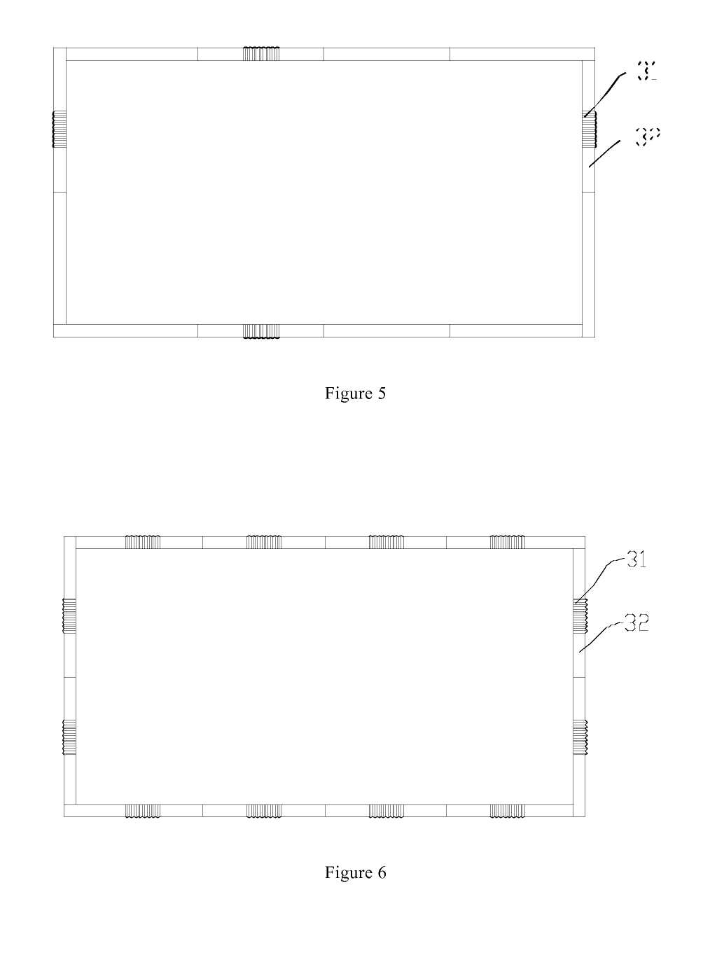

FIG. 6 shows a fourth example of the frame for an LCD device of the invention, and the fourth example is different from the third example in that: there are a plurality of ripple structures 31 in the edge frame provided with the ripple structure 31, each frame edge member is provided with the ripple structure 31. Both the length and width dimensions of the frame in the example can be adjusted. All the frame edge members 32 in the example can be of the same standard, namely the natural lengths of the frame edge member 32 are the same. Frames of various dimensions can be formed by joining only one kind frame edge member 32. Because the length and width dimensions of the joined frames may not meet requirements, the dimension can be adjusted within a certain range by using the adjustment capacity of the ripple structure 31 in the frame edge member 32. Other advantages are the same as those of the third example, and the fourth example will not give unnecessary details.

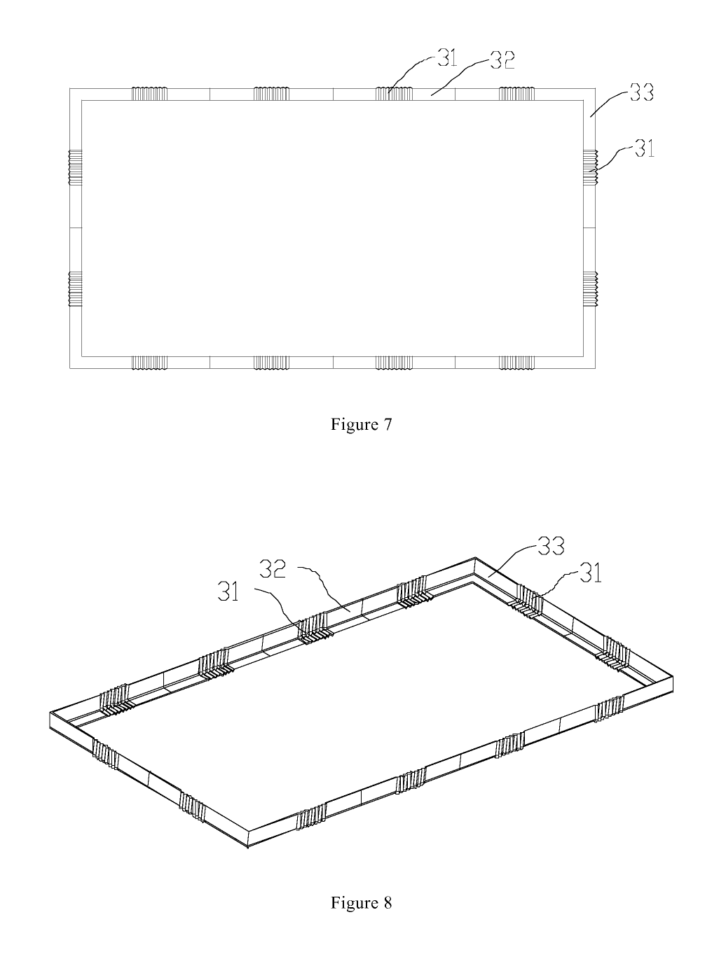

FIG. 7 and FIG. 8 show a fifth example of the frame for an LCD device of the invention, and the fifth example is different from the fourth example in that: the frame is formed by joining a plurality of frame edge members 32 and a plurality of frame corner members 33. The ripple structure 31 is arranged in the frame edge member 32 and the frame corner member 33. In the example, the frame comprises four frame corner members 33; one pair of edge frames in the length direction of the frame separately comprises two frame edge members 32, and all the frame edge members 32 and frame corner members 33 are separately provided with the ripple structure 31.

The example also employs the modular design, namely the frame is divided into a plurality of frame edge member and frame corner member units, and the designs of the frame edge member unit and frame corner member unit are standardized. Thus, the frame is formed by only matching and joining different number of frame edge members and frame corner members. The corner strength of the frame employing the frame corner members is higher. The length and width dimensions of the frame of the example can also be adjusted to achieve the effect of one object with multiple purposes.

Optionally, the ripple structure in the example can be only arranged in the frame edge member, or only arranged in the frame corner member. The aim of one object with multiple purposes can also be achieved.

The invention is described in detail in accordance with the above contents with the specific preferred examples. However, this invention is not limited to the specific examples. For the ordinary technical personnel of the technical field of the invention, on the premise of keeping the conception of the invention, the technical personnel can also make simple deductions or replacements, and all of which should be considered to belong to the protection scope of the invention.

We claim:

1. A frame for an LCD device, comprising: four edge frames; wherein at least one pair of mutually parallel edge frames of said four edge frames are separately provided with a ripple structure; said frame is formed by joining a plurality of frame edge members, and all said frame edge members are provided with said ripple structure; there are a plurality of said ripple structures in each edge frame with said ripple structure; the natural lengths of all said frame edge members are the same; said frame is formed by joining a plurality of frame edge members and a plurality of frame corner members.

2. A frame for an LCD device, comprising: four edge frames; wherein at least one pair of mutually parallel edge frames of said four edge frames are separately provided with a ripple structure.

3. The frame for an LCD device of claim 2, wherein there is a plurality of said ripple structures in said edge frame provided with said ripple structure.

4. The frame for an LCD device of claim 2, wherein said frame is formed by joining a plurality of frame edge members.

5. The frame for an LCD device of claim 4, wherein there is a plurality of said ripple structures in said edge frame provided with said ripple structure.

6. The frame for an LCD device of claim 5, wherein all said frame edge members are separately provided with said ripple structure, and the natural lengths of all said frame edge members are the same.

7. The frame for an LCD device of claim 2, wherein said frame is formed by joining a plurality of frame edge members and a plurality of frame corner members.

8. The frame for an LCD device of claim 7, wherein said ripple structure is arranged in the frame edge members or/and the frame corner members.

9. The frame for an LCD device of claim 8, wherein there is a plurality of said ripple structures in said edge frame provided with said ripple structure.

10. The frame for an LCD device of claim 9, wherein all said frame edge members and frame corner members are separately provided with said ripple structure.

11. An LCD device, comprising a frame; wherein said frame comprises four edge frames; at least one pair of mutually parallel edge frames of said four edge frames are separately provided with a ripple structure; said frame is a front frame or a middle frame.

12. The LCD device of claim 11, wherein there is a plurality of said ripple structures in said edge frame provided with said ripple structure.

13. The LCD device of claim 11, wherein said frame is formed by joining a plurality of frame edge members.

14. The LCD device of claim 13, wherein there is a plurality of said ripple structures in said edge frame provided with said ripple structure.

15. The LCD device of claim 14, wherein all said frame edge members are separately provided with said ripple structure, and the natural lengths of all said frame edge members are the same.

16. The LCD device of claim 11, wherein said frame is formed by joining a plurality of frame edge members and a plurality of frame corner members.

17. The LCD device of claim 16, wherein said ripple structure is arranged in said frame edge members or/and said frame corner members.

18. The LCD device of claim 17, wherein there is a plurality of said ripple structures in said edge frame provided with said ripple structure.

19. The LCD device of claim 18, wherein all said frame edge members and frame corner members are separately provided with said ripple structure.
